(19) United States
(12) Patent Application Publication
(10) Pub. No.: US 2024/0038938 A1
(43) Pub. Date: Feb. 1, 2024

(54) LIGHT-EMITTING STRUCTURE, MANUFACTURING METHOD THEREOF, AND LIGHT-EMITTING DEVICE

(71) Applicant: XIAMEN CHANGELIGHT CO., LTD., Xiamen (CN)

(72) Inventors: Xiaodong QU, Xiamen (CN); Kaixuan CHEN, Xiamen (CN); Hengping CUI, Xiamen (CN); Haifang CAI, Xiamen (CN); Yumei CAI, Xiamen (CN); Zhiwei LIN, Xiamen (CN); Kewei YANG, Xiamen (CN); Bin ZHAO, Xiamen (CN); Tudui JIANG, Xiamen (CN); Yan LI, Xiamen (CN); Minhua LI, Xiamen (CN); Guilan LUO, Xiamen (CN)

(73) Assignee: XIAMEN CHANGELIGHT CO., LTD., Xiamen (CN)

(21) Appl. No.: 18/380,139

(22) Filed: Oct. 13, 2023

Related U.S. Application Data
(63) Continuation of application No. PCT/CN2022/094089, filed on May 20, 2021.

(30) Foreign Application Priority Data
May 24, 2021 (CN) 202110562795.5
Apr. 25, 2022 (CN) 202210442069.4
Apr. 25, 2022 (CN) 202220968167.7
Apr. 27, 2023 (CN) 202310469186.4

(51) Int. Cl. H01L 33/40; H01L 33/44; H01L 33/22; H01L 33/00

(52) U.S. Cl. CPC H01L 33/405; H01L 33/44; H01L 33/22; H01L 33/0093

(57) ABSTRACT

A light-emitting structure, comprising: a substrate, and a first metal layer, an insulating layer, an integrated metal layer, and an epitaxial stack, disposed above the substrate. The integrated metal layer is disposed on a surface of the second-type semiconductor layer facing away from the active region, and the integrated metal layer comprises an exposed surface on a side of the integrated metal layer facing the second-type semiconductor layer, the exposed surface being configured to electrically connect with an external driving device.

### CROSS-REFERENCE TO RELATED PRESENT DISCLOSURES

This present disclosure is based on and claims priority to Chinese Patent Application No. CN 202310469186.4, filed on Apr. 27, 2023 and claims priority to PCT application No. PCT/CN2022/094089, filed on May 20, 2022, which claims priority to Chinese Patent Application No. CN202110562795.5, filed on May 24, 2021, Chinese Patent Application No. CN202210442069.4, filed on Apr. 25, 2022, and Chinese Patent Application No. CN202220968167.7, filed on Apr. 25, 2022, and to, the entire disclosures of which are incorporated herein by reference for all purposes.

### BACKGROUND

With the development of LED chip technology, great progress has been made in both vertical structure chips and flip structure chips. Especially the through-hole structure greatly improves the luminous efficiency of vertical structure chips and flip structure chips.

The through-hole structure is about opening a hole on the epitaxial surface to the N-type semiconductor, and leading the N-type contact to the chip surface through an electrical connection, so as to facilitate bonding or die bonding. As shown in FIG. 1, in order to conduct second-type semiconductor layer 33 in this structure, an ohmic reflective layer 4 needs to be prepared on the surface of the second-type semiconductor layer 33, and the ohmic reflection layer 4 is connected to the PAD metal layer 9 through the current spreading layer 8. However, the prior structure shown in FIG. 1 cannot achieve a balance between current expansion performance and product cost.

### SUMMARY

Embodiments of this present disclosure provide a light-emitting structure, a manufacturing method thereof, and a light-emitting device, so as to solve the technical problem of balancing and compromising between current expansion performance and product cost.

According to a first aspect of the present disclosure, some embodiments provide a light-emitting structure, comprising: a substrate, and a first metal layer, an insulating layer, an integrated metal layer, and an epitaxial stack, disposed above the substrate; wherein the epitaxial stack comprises a first-type semiconductor layer, an active region, and a second-type semiconductor layer, stacked in sequence along a direction, the direction being perpendicular to the substrate and being directed from the epitaxial stack to the substrate, the epitaxial stack has a through hole exposing a part of a surface of the first-type semiconductor layer, the integrated metal layer is disposed on a surface of the second-type semiconductor layer facing away from the active region, and the integrated metal layer comprises an exposed surface on a side of the integrated metal layer facing the second-type semiconductor layer, the exposed surface being configured to electrically connect with an external driving device; the insulating layer is disposed on a side of the epitaxial stack facing the substrate, covers the integrated metal layer and an exposed surface of the epitaxial stack; the first metal layer is stacked on a surface of the insulation layer facing away from the integrated metal layer, embedded in the through hole to form contact with the first-type semiconductor layer, and insulated from a sidewall of the through hole; and the substrate is stacked on a surface of the first metal layer facing away from the epitaxial stack.

According to a second aspect of the present disclosure, some embodiments provide a method for manufacturing a light-emitting structure, comprising: providing a growth substrate; preparing an epitaxial stack on a surface of the growth substrate, the epitaxial stack comprising a first-type semiconductor layer, an active region, and a second-type semiconductor layer, stacked in sequence along a direction, and the direction being perpendicular to the growth substrate and directed from the growth substrate to the epitaxial stack; forming a first through hole and a light-emitting mesa in the epitaxial stack by an etching process, the first through hole exposing a part of a surface of the first-type semiconductor layer; forming an ohmic reflective layer on the light-emitting mesa, the ohmic reflective layer being configured to perform ohmic contact and realize light reflection; depositing a first insulating layer, the first insulating layer filling the first through hole and extending to a sidewall of the ohmic reflective layer; preparing an integrated metal layer stacked on a surface of the ohmic reflective layer and the insulating layer; depositing a second insulating layer, the second insulating layer covering the integrated metal layer; forming a second through hole with the first insulating layer left on a side wall of the second through hole through an etching process; preparing a first metal layer to obtain an intermediate structure, the first metal layer being stacked on a surface of the insulating layer and embedded in the second through hole to form contact with the first-type semiconductor layer; fixing the intermediate structure on a substrate through a bonding process, the substrate being conductive and formed on a surface of the first metal layer; peeling off the growth substrate; and etching a part of the epitaxial stack so that the integrated metal layer has an exposed surface configured to electrically connect with an external driving device.

According to a third aspect of the present disclosure, some embodiments provide a light-emitting device, comprising: a driving device, configured to transmit a driving signal to a light-emitting structure; and the light-emitting structure according to the first aspect of the present disclosure.

### BRIEF DESCRIPTION OF THE DRAWINGS

In order to more clearly illustrate the technical solutions in the embodiments of the present disclosure or the prior art, the following will briefly introduce the drawings that need to be used in the description of the present disclosure. The accompanying drawings in the following description are only examples provided by embodiments of the present disclosure, and those skilled in the art can also obtain other drawings according to the provided drawings without creative work.

FIG. 1 is a schematic structural view of a through-hole LED chip in the prior art;

FIG. 2 is a schematic structural view of a first implementation of an LED chip provided in an embodiment of the present disclosure;

FIGS. 2A to 2L are structural schematic diagrams corresponding to the steps of the method for manufacturing the LED chip provided in FIG. 2 in the embodiment of the present disclosure;

FIG. 3 is a schematic structural diagram of a second implementation of the LED chip provided in the embodiment of the present disclosure;

FIG. 3A to FIG. 3N are structural schematic diagrams corresponding to the steps of the manufacturing method of the LED chip provided in FIG. 2 in the embodiment of the present disclosure;

FIG. 4 is a schematic structural diagram of a vertical structure LED chip provided by an embodiment of the present disclosure;

FIG. 5 is a sectional view of the vertical structure LED chip provided in FIG. 2 along the AA′ direction in the embodiment of the present disclosure;

FIG. 6A to FIG. 6P are structural schematic diagrams corresponding to the steps of the method for manufacturing the vertical structure LED chip provided by the embodiment of the present disclosure.

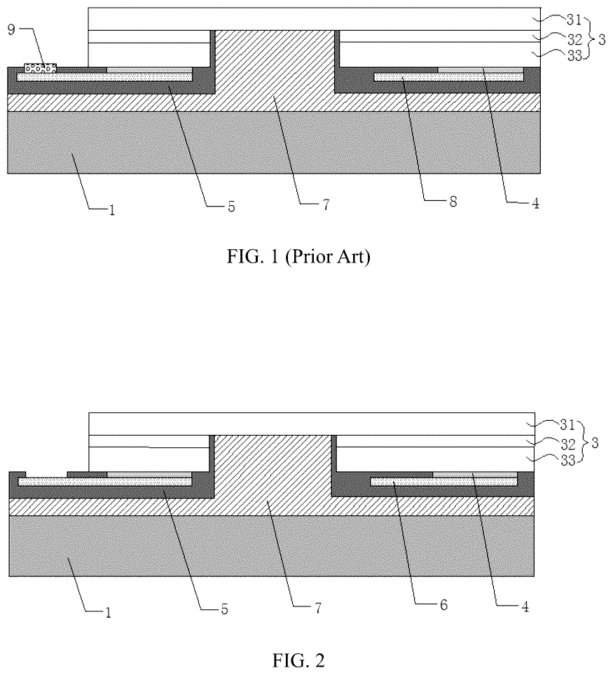

### DETAILED DESCRIPTION

In order to make the content of this present disclosure clearer, the content of this present disclosure will be further described below in conjunction with the accompanying drawings. The present disclosure is not limited to this specific example. Based on the embodiments in this present disclosure, all other embodiments obtained by persons of ordinary skill in the art without making creative efforts belong to the scope of protection of this present disclosure.

For light-emitting devices, improving the quantum efficiency is an eternal subject pursued by R&D workers. Among them, the current expansion and the design of the reflector are the key objects to be overcome at the structural level of the vertical structure chip. The better the expansion ability of the current expansion layer, the lower the voltage, the more uniform the current distribution, and the higher the light efficiency. In order to increase the expansion capability, the current spreading layer is usually realized by using high-conductivity metal or increasing the thickness. However, high-conductivity metals usually have active chemical properties (such as Ag, Cu, Al, Ca, Mg, etc.), or are too expensive (such as Au, etc.). Thus, it is normally required to make a balance and compromise between product costs and current expansion performance, for example, choose metals with relatively high resistivity such as Ti, W, Pt, Cr, etc., and achieve current expansion by increasing the thickness. In order to improve the reflectivity, high-reflective metals are usually used as reflectors, and the high-reflective metals may contain any one or any combination of Ag, Au, Al, Mg, Ni, Ti, etc. However, there is still a certain gap for the reflective metal to reach the reflective rate of 100%. Some of the embodiments of the present disclosure are described based on an exemplary LED structure. However, the light-emitting structure provided by embodiments may be applied in a light-emitting system rather than LED.

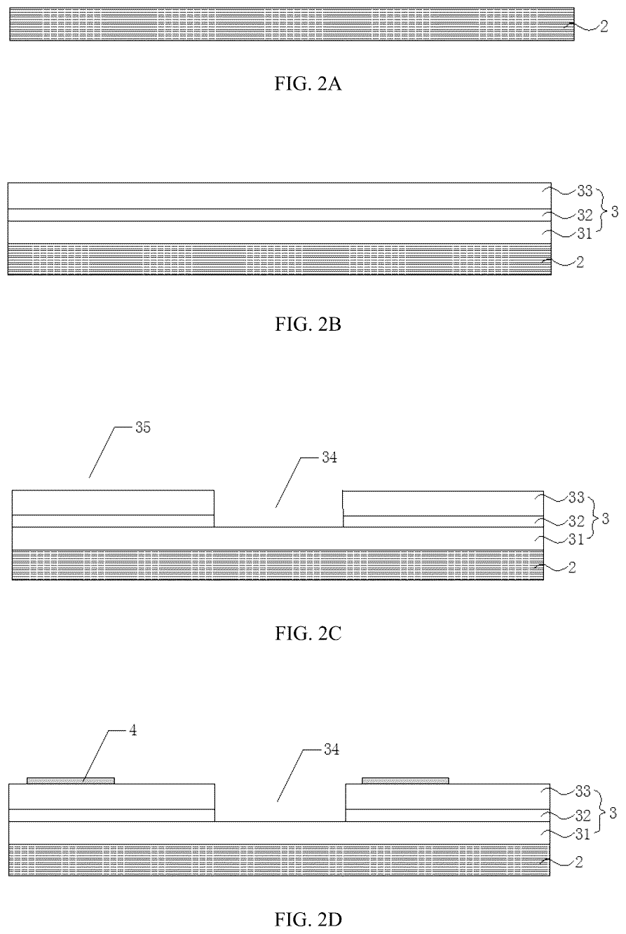

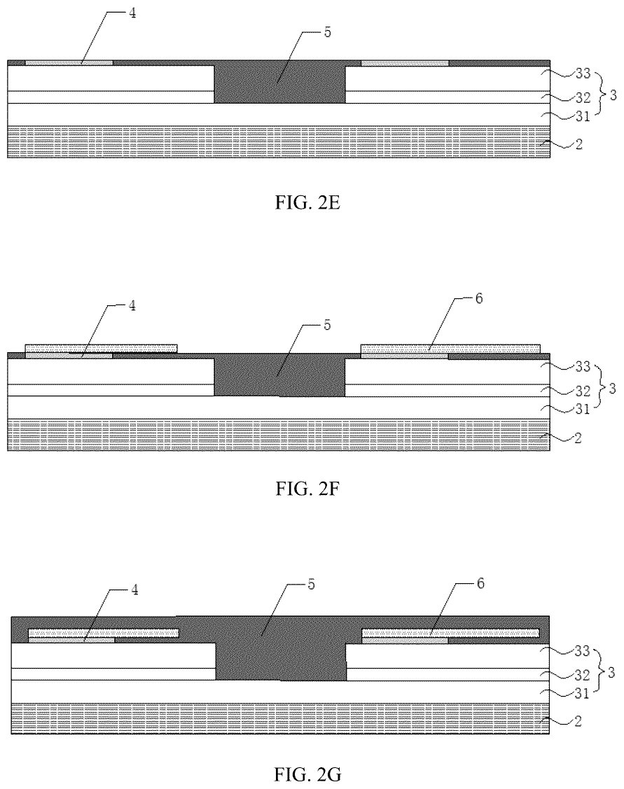

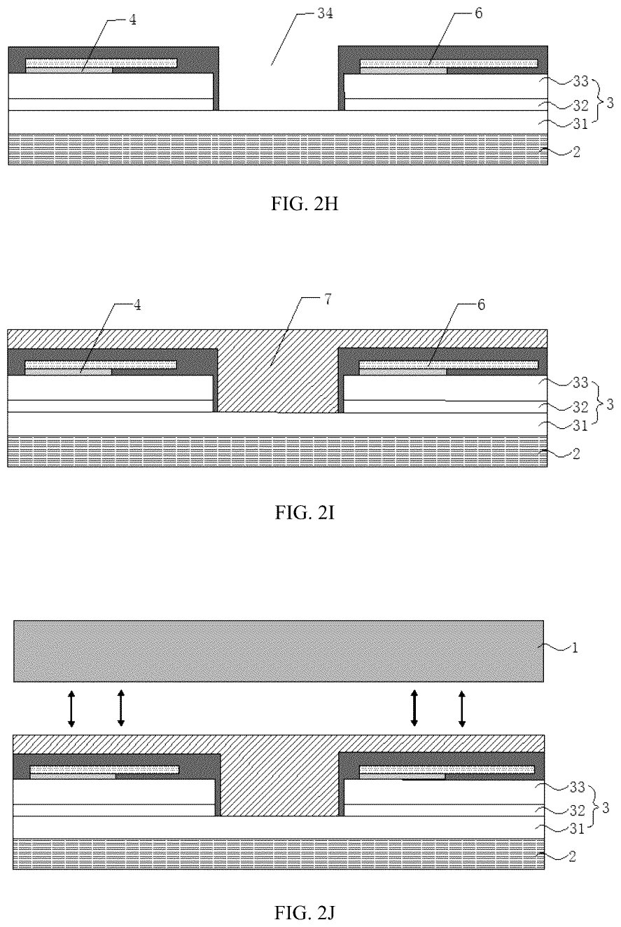

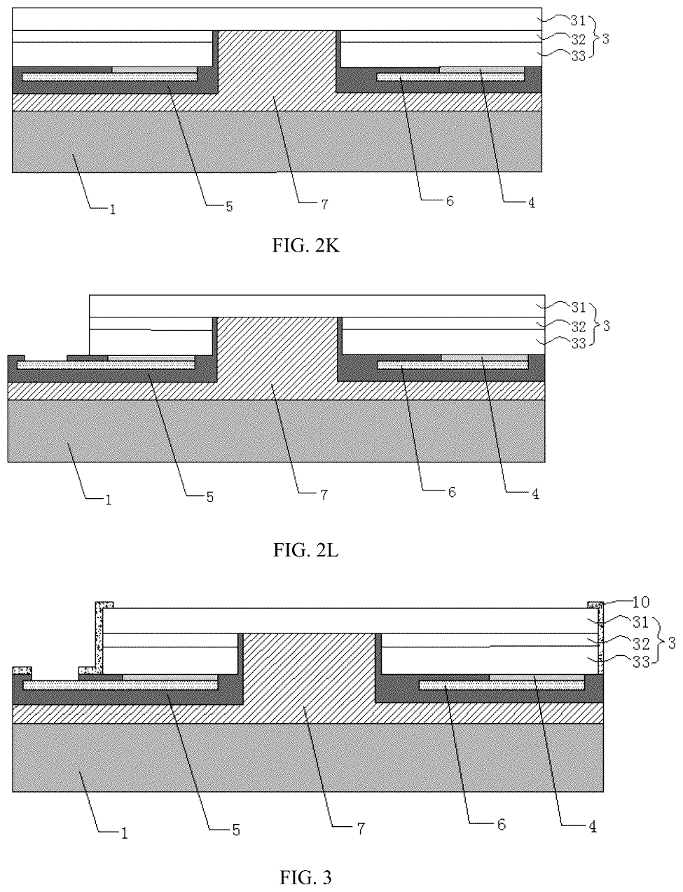

As shown in FIG. 2, some embodiments of the present disclosure provide an LED chip, which includes a substrate 1, and a first metal layer 7, an insulating layer an integrated metal layer 6 and an epitaxial stack 3, disposed above the substrate 1. The epitaxial stack 3 at least includes a second-type semiconductor layer 33, an active region 32 and a first-type semiconductor layer 31, stacked in sequence along a first direction, and the epitaxial stack 3 has a through hole 34 exposing a part of a surface of the first-type semiconductor layer 31; the first direction is perpendicular to the substrate 1, and is directed from the substrate 1 to the epitaxial stack 3.

The integrated metal layer 6 is disposed on a surface of the second-type semiconductor layer 33 facing away from the active region 32, and a side of the integrated metal layer 6 facing the second-type semiconductor layer 33 is provided with an exposed surface for electrically connecting with an external driving device. The external driving device is configured to transmit a driving signal for driving the LED chip to emit light. The driving signal may be an electrical signal, for example, a constant-voltage electrical signal or a constant-current electrical signal. However, the type of the driving signal is not limited to the embodiments of the present disclosure.

The insulating layer 5 is provided on the side of the epitaxial stack 3 facing the substrate 1, and covers the integrated metal layer 6, the exposed surface of the epitaxial stack 3, and extends to the side wall of the through hole 34;

The first metal layer 7 is stacked on a surface of the insulating layer 5 facing away from the integrated metal layer 6, and embedded in the through hole 34 to form contact with the first-type semiconductor layer 31, and the substrate 1 is stacked on a surface of the first metal layer 7 facing away from the epitaxial stack 3.

The types of the first-type semiconductor layer 31, the active region 32, and the second-type semiconductor layer 33 of the epitaxial stack 3 are not limited in embodiments of the present disclosure. For example, the first-type semiconductor layer 31 may be but not limited to a gallium nitride layer, and correspondingly, the second-type semiconductor layer 33 may be but not limited to a gallium nitride layer.

Meanwhile, the specific types of the insulating layer 5 and the first metal layer 7 are not limited in the embodiments of the present disclosure, as long as the above requirements are met.

In some embodiments, the integrated metal layer 6 includes Au metal material.

In some embodiments, the sidewall of the integrated metal layer 6 is covered by the insulating layer 5.

In some embodiments of the present disclosure, an ohmic reflective layer 4 capable of ohmic contact and light reflection is provided on the surface of the integrated metal layer 6 facing the second-type semiconductor layer 33.

In some embodiments of the present disclosure, the ohmic reflective layer 4 includes any one or any combination of indium, tin, aluminum, Au, platinum, zinc, silver, titanium, lead, and nickel.

In some embodiments of the present disclosure, the substrate 1 includes a conductive substrate 1.

Some embodiments of the present disclosure provide a method for manufacturing an LED chip, comprising the following steps:

S201, as shown in FIG. 2A, provide a growth substrate 2;

S202, as shown in FIG. 2B, stack an epitaxial stack 3 on a surface of the growth substrate 2, the epitaxial stack 3 includes the first-type semiconductor layer 31, the active region 32 and the second-type semiconductor layer 33, stacked in sequence along a first direction, the first direction is perpendicular to the growth substrate 2, and is directed from the growth substrate 2 to the epitaxial stack 3;

S203, as shown in FIG. 2C, form a through hole 34 and a light-emitting mesa 35 in the epitaxial stack 3 through an etching process, and the through hole 34 exposes part of a surface of the first-type semiconductor layer 31;

S204, as shown in FIG. 2D, form an ohmic reflective layer 4 on the light-emitting mesa 35, and the ohmic reflective layer 4 is configured to perform ohmic contact and realize light reflection;

S205, as shown in FIG. 2E, deposit an insulating layer 5, the insulating layer 5 fills the through hole 34 and extends to the sidewall of the ohmic reflective layer 4;

S206, as shown in FIG. 2F, prepare the integrated metal layer 6, and the integrated metal layer 6 is stacked on a surface of the ohmic reflective layer 4 and the insulating layer 5;

S207, as shown in FIG. 2G, deposit an insulating layer 5 again, so that the insulating layer 5 covers the integrated metal layer 6, and makes the surface of the epitaxial stack 3 form a plane;

S208. As shown in FIG. 2H, through an etching process, a through hole 34 having an insulating layer 5 on the side wall is formed;

S209, as shown in FIG. 2I, prepare the first metal layer 7, the first metal layer 7 is stacked on a surface of the insulating layer 5, and embedded in the through hole 34 to form contact with the first-type semiconductor layer 31;

S210. As shown in FIG. 2J, the chip structure formed in step S209 is fixed on the conductive substrate 1 through a bonding process, and the substrate 1 is formed on a surface of the first metal layer 7;

S211, as shown in FIG. 2K, peel off the growth substrate 2;

S212. As shown in FIG. 2L, etch a part of the epitaxial stack 3 to the insulating layer 5, so that the integrated metal layer 6 has an exposed surface for electrically connecting with an external driving device.

In some embodiments of the present disclosure, step S212 includes making the sidewall of the integrated metal layer 6 covered by the insulating layer 5 through an etching process.

In some embodiments of the present disclosure, the integrated metal layer 6 includes Au metal material.

In some embodiments of the present disclosure, the ohmic reflective layer 4 includes any one or any combination of indium, tin, aluminum, Au, platinum, zinc, silver, titanium, lead, and nickel.

It can be known from the above technical solutions that the LED chip provided by some embodiments of the present disclosure is provided with an integrated metal layer 6 on the surface of the second-type semiconductor layer 33 facing away from the active region 32, and the surface of integrated metal layer 6 facing the second-type semiconductor layer 33 is provided with an exposed surface for electrical connection with the external driving device; the insulating layer 5 is provided on the side of the epitaxial stack 3 facing the substrate, covers the integrated metal layer 6 and the exposed surface of the epitaxial stack 3, and extends to the sidewall of the through hole 34. Thus, the current spreading layer 8 and the PAD metal layer 9 in the prior structure are integrated by forming the integrated metal layer 6, and the current spreading layer 8 is replaced by the integrated metal layer 6. In some embodiments, Au-containing metal materials are used in the process of preparing the integrated metal layer 6. Since the resistivity of the Au metal material is low, which can achieve better current expansion capability; in addition, a part of the surface in the integrated metal layer 6 is exposed by etching, and the exposed surface of the integrated metal layer 6 undertakes the function of the PAD metal layer 9 in the prior structure, which can realize with external electrical connection. In this way, the PAD metal layer 9 is not required to be separately prepared, and the cost is saved. In addition, different from the traditional PAD metal layer 9, the side wall of the integrated metal layer 6 is covered in the insulating layer 5, which can better withstand the erosion of external water vapor, acid and alkali, salt spray, etc., and improves the reliability of the chip.

The manufacturing method of the LED chip provided by the embodiments of the present disclosure realizes the above-mentioned beneficial effect of the LED chip with a filled through hole 34, and at the same time, the manufacturing process is simple and convenient, saves the process of separately manufacturing the PAD metal layer 9, saves the cost, and is convenient for production.

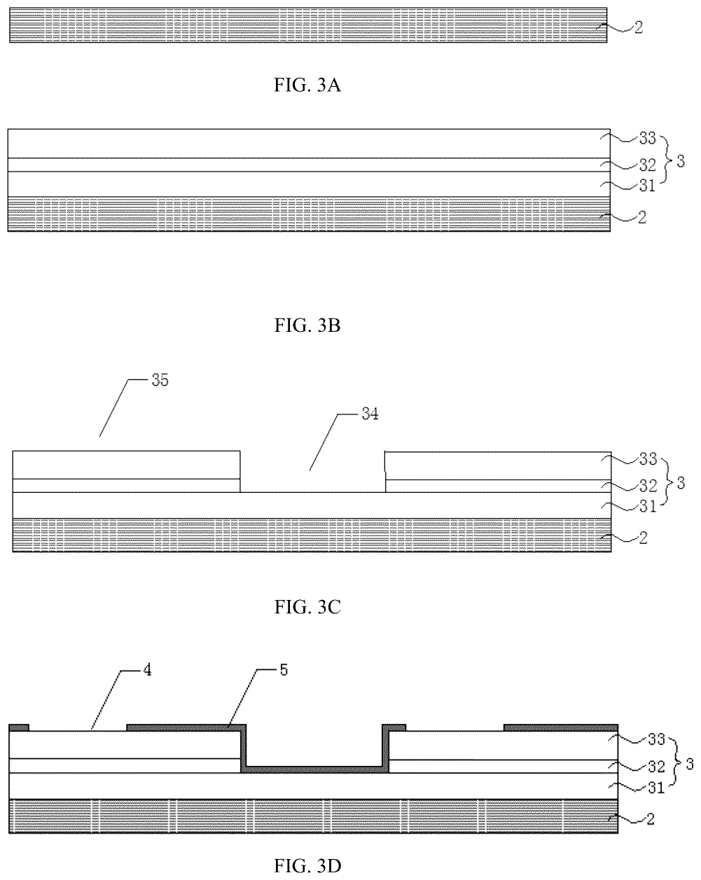

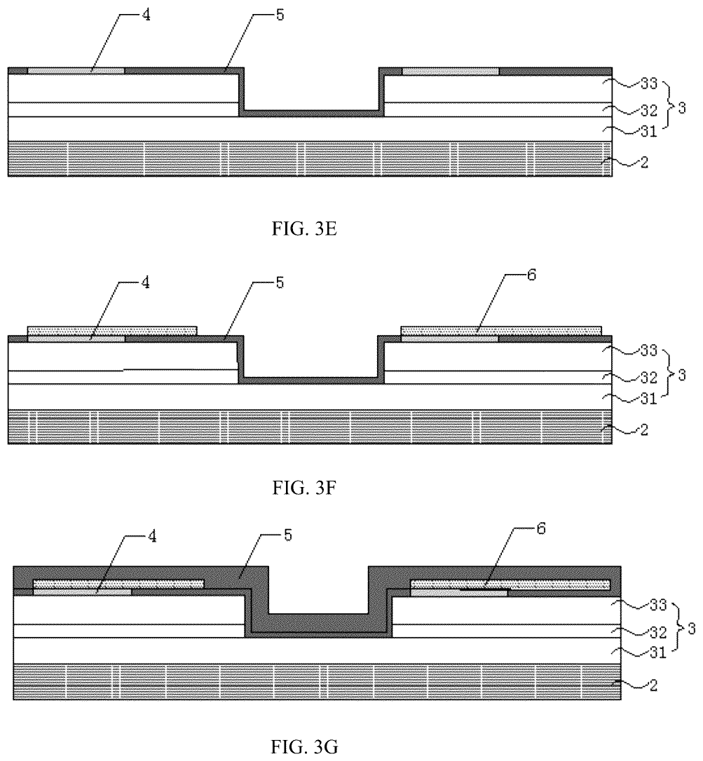

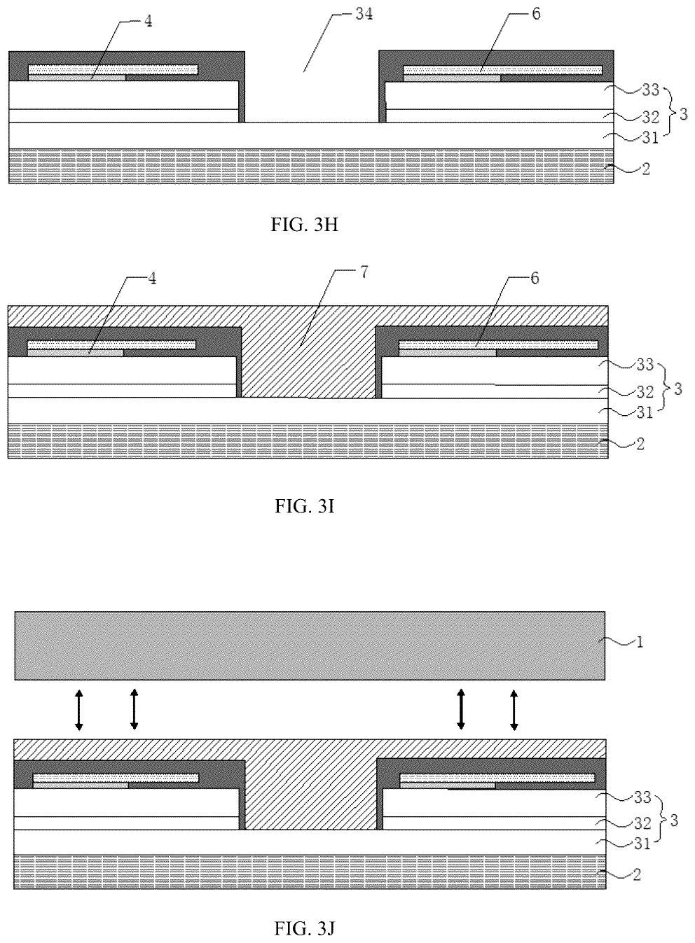

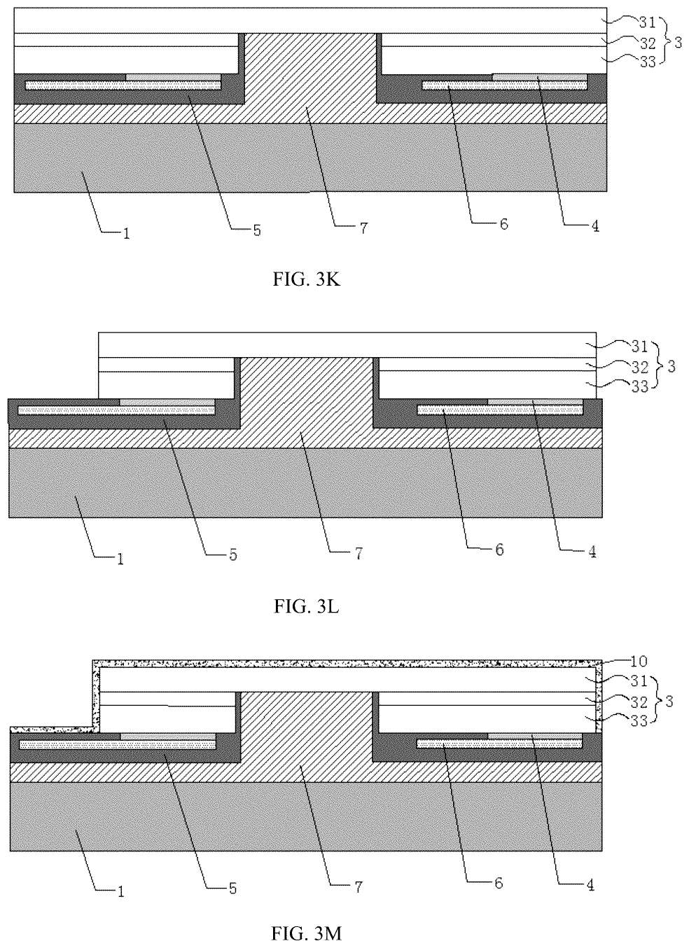

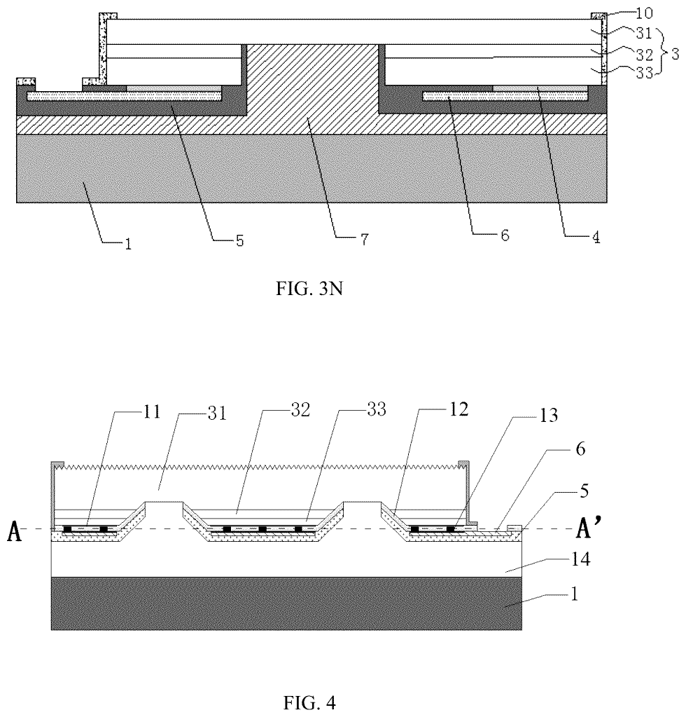

As shown in FIG. 3, some embodiments of the present disclosure provide an LED chip, which includes:

the substrate 1, and the first metal layer 7, the insulating layer 5, the integrated metal layer 6 and the epitaxial stack 3, disposed above the substrate 1. The epitaxial stack 3 at least includes a second-type semiconductor layer 33, the active region 32 and the first-type semiconductor layer 31, stacked in sequence along a first direction, and the epitaxial stack 3 has a through hole 34 exposing a part of the surface of the first-type semiconductor layer 31; the first direction is perpendicular to the substrate 1, and is directed from the substrate 1 to the epitaxial stack 3.

The integrated metal layer 6 is stacked on the surface of the second-type semiconductor layer 33 facing away from the active region 32, and the side of the integrated metal layer 6 facing the second-type semiconductor layer 33 is provided with an exposed surface for electrically connecting with an external driving device. On a surface of the integrated metal layer 6 facing the second-type semiconductor layer 33, an ohmic reflective layer 4 configured to perform ohmic contact and realize light reflection is provided;

The insulating layer 5 is provided on the side of the epitaxial stack 3 facing the substrate 1, and covers the integrated metal layer 6, the exposed surface of the epitaxial stack 3, and extends to the side wall of the through hole 34;

The first metal layer 7 is stacked on the surface of the insulating layer 5 away from the integrated metal layer 6, and embedded in the through hole 34 to form contact with the first-type semiconductor layer 31, and the substrate 1 is stacked on a surface of the first metal layer 7 facing away from the epitaxial stack 3;

A passivation layer 10 is provided on a sidewall of the epitaxial stack 3. It can be seen from the comparison that the embodiment shown in FIG. 3 further includes the passivation layer 10, compared to the embodiment shown in FIG. 2.

The types of the first-type semiconductor layer 31, the active region 32, and the second-type semiconductor layer 33 of the epitaxial stack 3 are not limited in embodiments of the present disclosure. For example, the first-type semiconductor layer 31 may be but not limited to a gallium nitride layer, and correspondingly, the second-type semiconductor layer 33 may be but not limited to a gallium nitride layer.

Meanwhile, the specific types of the insulating layer 5 and the first metal layer 7 are not limited in the embodiments of the present disclosure, as long as the above requirements are met.

In some embodiments of the present disclosure, the integrated metal layer 6 includes but is not limited to any one or any combination of Au, copper, palladium, and aluminum.

In some embodiments of the present disclosure, the sidewall of the integrated metal layer 6 is covered by the insulating layer 5.

In some embodiments of the present disclosure, the ohmic reflective layer 4 includes but is not limited to any one or any combination of indium tin oxide, zinc tin oxide, indium zinc tin oxide, indium aluminum tin oxide, indium gallium tin oxide, aluminum zinc oxide, antimony tin oxide, gallium zinc oxide, IrOx, RuOx, indium, tin, aluminum, Au, platinum, zinc, silver, titanium, lead, nickel, rhodium, molybdenum.

In some embodiments of the present disclosure, the substrate 1 includes a conductive substrate.

In some embodiments of the present disclosure, the passivation layer 10 includes but not limited to any one or any combination of a SiOxNy passivation layer, a Al₂O₃ passivation layer, a MgF passivation layer, and a TiOx passivation layer, wherein, x≥0, y≥0.

In some embodiments of the present disclosure, the epitaxial stack 3 has at least one exposed insulating surface, which extends from the first-type semiconductor layer 31 to the insulating layer 5 through the active region 32 and the second-type semiconductor layer 33. The passivation layer 10 is attached to the sidewall of the epitaxial stack 3 by being kept on the exposed insulating.

In some embodiments of the present disclosure, the exposed insulating surface surrounds the sidewall of the epitaxial stack 3. The passivation layer 10 surrounds the sidewall of the epitaxial stack 3 by being kept on the exposed insulating.

Some embodiments of the present disclosure provide a method for manufacturing an LED chip, including the following steps:

S301, as shown in FIG. 3A, provide a growth substrate 2;

S302, as shown in FIG. 3B, stack an epitaxial stack 3 on the surface of the growth substrate 2, the epitaxial stack 3 includes the first-type semiconductor layer 31, the active region 32, and the second-type semiconductor layer 33, stacked in sequence along a first direction, the first direction is perpendicular to the growth substrate 2, and is directed from the growth substrate 2 to the epitaxial stack 3;

S303, as shown in FIG. 3C, form a through hole 34 and a light-emitting mesa 35 in the epitaxial stack 3 through an etching process, and the through hole 34 exposes part of the surface of the first-type semiconductor layer 31;

S304, as shown in FIG. 3D, deposit an insulating layer 5, the insulating layer 5 covers the surface of the epitaxial stack 3, the side wall and the bottom surface of the through hole 34, and pattern the insulating layer 5 to expose a part of the light-emitting mesa 35;

S305, as shown in FIG. 3E, form an ohmic reflective layer 4 on the exposed surface of the light-emitting mesa 35, and the ohmic reflective layer 4 is configured to perform ohmic contact and realize light reflection;

S306, as shown in FIG. 3F, prepare the integrated metal layer 6, and the integrated metal layer 6 is stacked on the surface of the ohmic reflective layer 4 and the insulating layer 5;

S307, as shown in FIG. 3G, deposit an insulating layer 5 again, so that the insulating layer 5 covers the integrated metal layer 6;

S308, as shown in FIG. 3H, through an etching process, form a through hole 34 with an insulating layer 5 on the side wall;

S309, as shown in FIG. 3I, prepare the first metal layer 7, the first metal layer 7 is stacked on the surface of the insulating layer 5, and embedded in the through hole 34 to form contact with the first-type semiconductor layer 31;

S310, as shown in FIG. 3J, fix the chip structure formed in step S309 on the conductive substrate 1 through a bonding process, and the substrate 1 is formed on the surface of the first metal layer 7;

S311, as shown in FIG. 3K, peel off the growth substrate 2;

S312. as shown in FIG. 3L, etching part of the epitaxial stack 3 so that the insulating layer 5 has the exposed surface for electrically connecting with an external driving device;

S313. as shown in FIG. 3M, deposit a passivation layer 10, the passivation layer 10 covering the exposed surfaces of the epitaxial stack 3 and the insulating layer 5;

S314, as shown in FIG. 3N, pattern the passivation layer 10 and the insulating layer 5 by photolithography and etching, to expose a part of the surface of the first-type semiconductor layer 31 and a part of the surface of the integrated metal layer 6.

In some embodiments of the present disclosure, in the step S314, the pattern of the passivation layer 10 and the exposed surface of the integrated metal layer 6 are formed by one photolithography step.

In some embodiments of the present disclosure, step S314 includes making the sidewall of the integrated metal layer 6 covered by the insulating layer 5 through an etching process.

In some embodiments of the present disclosure, the integrated metal layer 6 includes but is not limited to any one or any combination of Au, copper, palladium, and aluminum. In some embodiments of the present disclosure, the ohmic reflective layer 4 is made of any one or any combination of indium tin oxide, zinc tin oxide, indium zinc tin oxide, indium aluminum tin oxide, indium gallium tin oxide, aluminum zinc oxide, antimony tin oxide, gallium zinc oxide, IrOx, RuOx, indium, tin, aluminum, Au, platinum, zinc, silver, titanium, lead, nickel, rhodium, molybdenum. Further, in some embodiments of the present disclosure, the epitaxial stack 3 has at least one exposed insulating surface, the exposed insulating surrounds the sidewall of the epitaxial stack 3, and the passivation layer 10 is arranged surrounding the side wall of the epitaxial stack 3 by being kept on the exposed insulating surface.

It can be known from the above technical solutions that the LED chip provided by some embodiments of the present disclosure is provided with an integrated metal layer 6 on the surface of the second-type semiconductor layer 33 facing away from the active region 32, and the surface of integrated metal layer 6 facing the second-type semiconductor layer 33 is provided with an exposed surface for electrical connection with the external driving device; the insulating layer 5 is provided on the side of the epitaxial stack 3 facing the substrate, covers the integrated metal layer 6 and the exposed surface of the epitaxial stack 3, and extends to the sidewall of the through hole 34. Thus, the current spreading layer 8 and the PAD metal layer 9 in the prior structure are integrated by forming the integrated metal layer 6, and the current spreading layer 8 is replaced by the integrated metal layer 6. In some embodiments, Au-containing metal materials are used in the process of preparing the integrated metal layer 6. Since the resistivity of the Au metal material is low, which can achieve better current expansion capability; in addition, a part of the surface in the integrated metal layer 6 is exposed by etching, and the exposed surface of the integrated metal layer 6 undertakes the function of the PAD metal layer 9 in the prior structure, which can realize with external electrical connection. In this way, the PAD metal layer 9 is not required to be separately prepared, and the cost is saved. In addition, different from the traditional PAD metal layer 9, the side wall of the integrated metal layer 6 is covered in the insulating layer 5, which can better withstand the erosion of external water vapor, acid, and alkali, salt spray, etc., and improves the reliability of the chip.

At the same time, a passivation layer 10 for protecting the LED chip is provided on the sidewall of the epitaxial stack 3, and based on this structure, the passivation layer 10 and the insulating layer 5 can be patterned in one photolithography and etching process. Therefore, the surface of the first-type semiconductor layer 31 and part of the surface of the integrated metal layer 6 are exposed, so that the passivation of the side wall of the LED chip and the manufacture of the PAD can be realized.

The manufacturing method of the LED chip provided by the embodiments of the present disclosure realizes the above-mentioned beneficial effect of the LED chip with a filled through hole 34, and the manufacturing process is simple and convenient, saving the process of separately manufacturing the PAD metal layer 9, and the passivation layer and the insulating layer can be patterned in one photolithography and etching process, which saves cost and facilitates production.

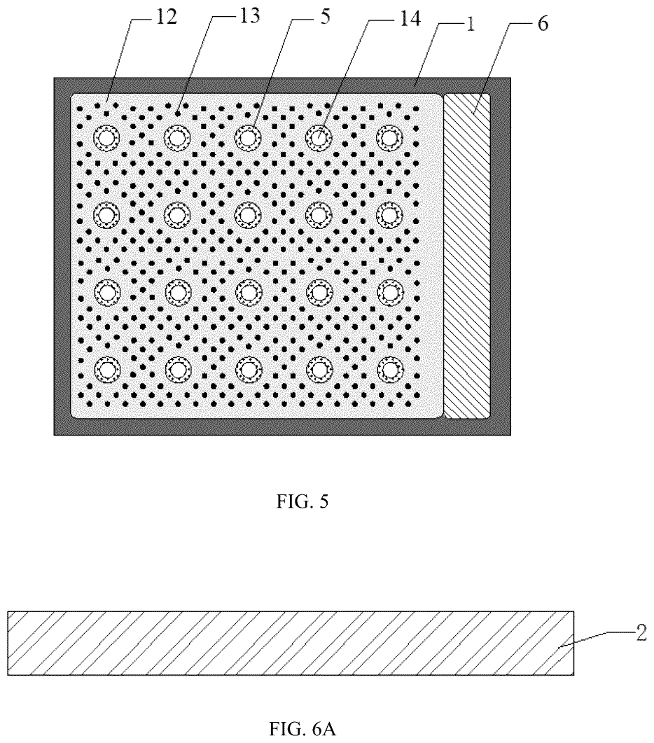

As shown in FIG. 4 and FIG. 5, some embodiments of the present disclosure provide a vertical structure LED chip, which includes: the substrate 1, and the conductive bonding layer 14, the insulating layer 5, the integrated metal layer 6, the dielectric layer 12, the metal reflective layer 13, and the epitaxial stack 3, arranged above the substrate 1. The epitaxial stack 3 includes at least the second-type semiconductor layer 33, the active region 32, and the first-type semiconductor layer 31, sequentially stacked along the first direction, and the epitaxial stack 3 has a through hole 34 exposing a part of the surface of the first-type semiconductor layer 31. The first direction is perpendicular to the substrate 1 and directed from the substrate 1 to the epitaxial stack 3.

The dielectric layer 12 is stacked on a surface of the second-type semiconductor layer 33 facing away from the active region 32, and the metal reflection layer 13 is in contact with the second-type semiconductor layer 33 through an opening 121 embedded in the dielectric layer 12.

The integrated metal layer 6 is stacked on a surface of the metal reflective layer 13 facing away from the epitaxial stack 3, and a side of the integrated metal layer 6 facing the second-type semiconductor layer 33 is provided with an exposed surface for electrically connecting with an external driving device. The external driving device is configured to transmit a driving signal for driving the LED chip to emit light.

The insulating layer 5 is provided on the side of the epitaxial stack 3 facing the substrate 1, and covers the integrated metal layer 6;

The conductive type bonding layer 14 is stacked on a surface of the insulation layer 5 facing away from the integrated metal layer 6, and embedded in the through hole 34 to form contact with the first-type semiconductor layer 31. The conductive bonding layer 14 is insulated from the sidewall of the through hole 34, and the substrate 1 is stacked on a surface of the conductive bonding layer 14 facing away from the epitaxial stack 3.

The types of the first-type semiconductor layer 31, the active region 32, and the second-type semiconductor layer 33 of the epitaxial stack 3 are not limited in embodiments of the present disclosure. For example, the first-type semiconductor layer 31 It may be but not limited to an N-type GaN layer, and correspondingly, the second-type semiconductor layer 33 may be but not limited to a P-type GaN layer.

Meanwhile, the specific types of the insulating layer 5 and the conductive bonding layer 14 are not limited in the embodiments of the present disclosure, as long as the above requirements are met. In one embodiment of the present disclosure, the conductive bonding layer 14 is made of any one or any combination of Au, In, Ni, Sn, Ag, and Cu. In some embodiments, the insulating layer 5 includes but is not limited to a silicon dioxide layer.

In an embodiment of the present disclosure, the insulating layer 5 extends to the sidewall of the through hole 34 to insulate the conductive bonding layer 14 from the sidewall of the through hole 34.

In an embodiment of the present disclosure, the dielectric layer 12 has m openings 121, where m is a positive integer not less than 2. In order to highlight the technical solution points of the present disclosure, FIGS. 4 and 5 only illustrate some exemplary openings 121 of the dielectric layer 12. In actual use, the dielectric layer 12 may contain several openings, depending on the situation. However, the present disclosure does not limit the number and the specific arrangement of the openings 121.

In an embodiment of the present disclosure, the vertical LED chip has n through holes 34, where n is a positive integer not less than 2. In order to highlight the technical solution points of the present disclosure, FIG. 4 and FIG. 5 only illustrate some through holes of the vertical structure LED chip. In the actual use process, the vertical structure LED chip may contain several through holes depending on the specific situation, which is not limited in the present disclosure.

In an embodiment of the present disclosure, a filling structure may also be provided in the through hole, and the filling structure includes independent epitaxial pillars formed by etching in the epitaxial stack, or the filling structure includes any one or any combination of insulating materials and metals. On the premise of ensuring that the conductive type bonding layer 14 is in contact with the first-type semiconductor layer 31, the filling structure reduces the surface height difference caused by the through hole 34 and the resulting void, thereby solving the technical problems of stress mismatch, heat accumulation, and uneven current distribution.

In an embodiment of the present disclosure, the dielectric layer 12 includes any one or any combination of a silicon oxide layer, a silicon nitride layer, a silicon oxynitride layer, a titanium oxide layer, an aluminum oxide layer, a magnesium fluoride layer, and a hafnium oxide layer.

In an embodiment of the present disclosure, the metal reflective layer 13 includes any one or any combination of an aluminum metal layer, a silver metal layer, an Au metal layer, a platinum metal layer, a lead metal layer, a nickel metal layer, an indium metal layer, a zinc metal layer, a chromium metal layer, a niobium metal layer, a titanium metal layer, a tin metal layer, and a rhodium metal layer.

In an embodiment of the present disclosure, the first-type semiconductor layer 31 has a roughened surface on a side facing away from the active region 32.

In an embodiment of the present disclosure, an ohmic contact layer 11 is provided on a surface of the second-type semiconductor layer 33 facing away from the active region 32, and the dielectric layer 12 is stacked on a surface of the ohmic contact layer 11, and the ohmic contact layer 11 forms ohmic contact with the metal reflective layer 13. The ohmic contact layer 11 is used to promote the ohmic contact between the metal and the semiconductor layer.

In some embodiments of the present disclosure, the ohmic contact layer 11 includes a metal ohmic contact layer 11 or a transparent conductive layer. In an embodiment of the present disclosure, in order to avoid the light being absorbed by metal, the ohmic contact layer 11 may be a transparent conductive layer.

In an embodiment of the present disclosure, a passivation protection layer 10 is provided on the sidewall of the epitaxial stack 3, and the passivation protection layer 10 is made of insulating materials. In an embodiment, the passivation protection layer 10 includes an insulating material layer having a reflection effect. In an embodiment, the passivation protection layer 10 may include a DBR (Distributed Bragg Reflector) mirror.

In an embodiment of the present disclosure, the integrated metal layer 6 includes Au metal material.

In an embodiment of the present disclosure, the sidewall of the integrated metal layer 6 is covered by the insulating layer 5.

In an embodiment of the present disclosure, the substrate 1 includes a conductive substrate 1.

In an embodiment of the present disclosure, the dielectric layer 12 extends to the sidewall of the through hole 34.

In an embodiment of the present disclosure, the metal reflective layer 13 extends to the sidewall of the through hole 34 by being attached to the dielectric layer 12, and the insulating layer 5 covers a surface of the metal reflective layer 13.

Some embodiments of the present disclosure also provide a method for manufacturing a vertical structure LED chip, comprising the following steps:

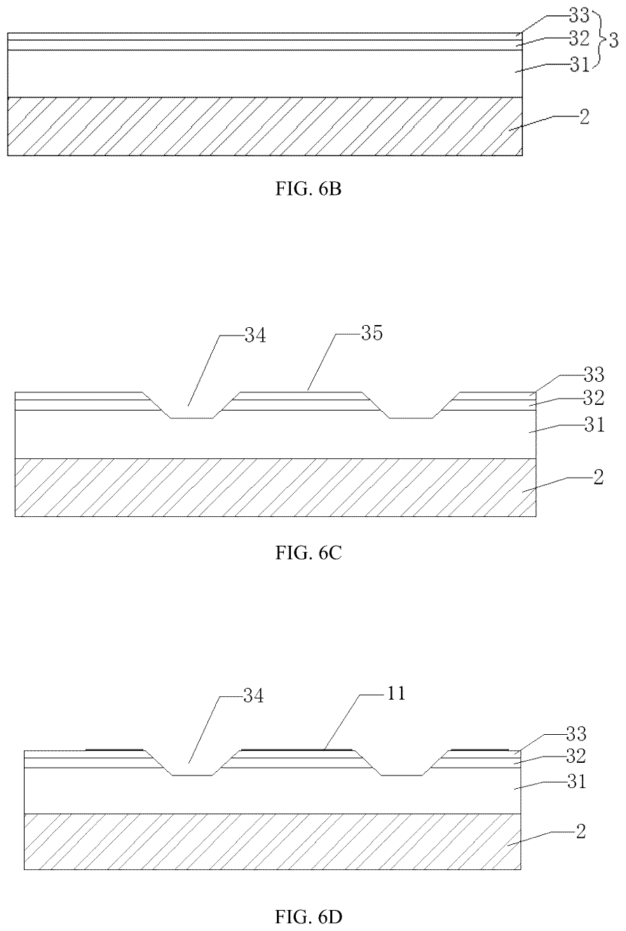

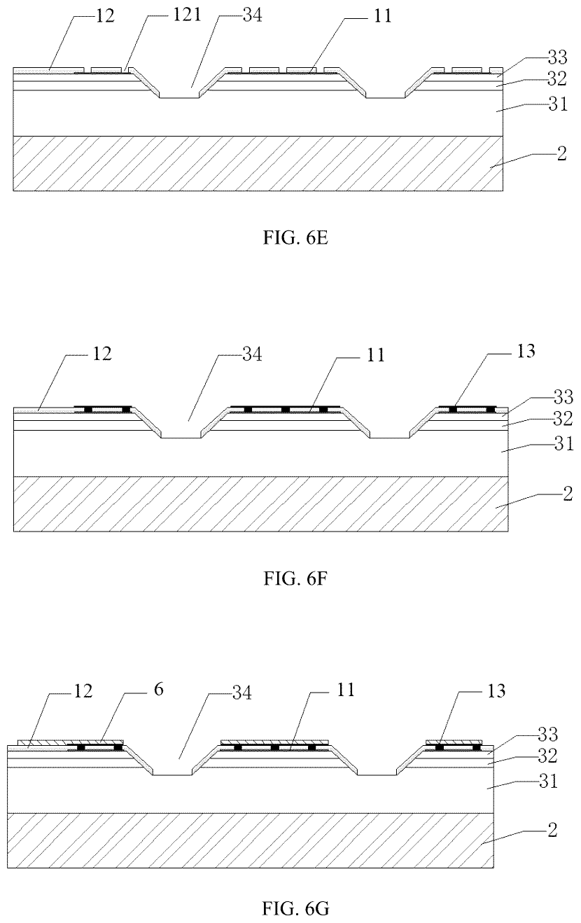

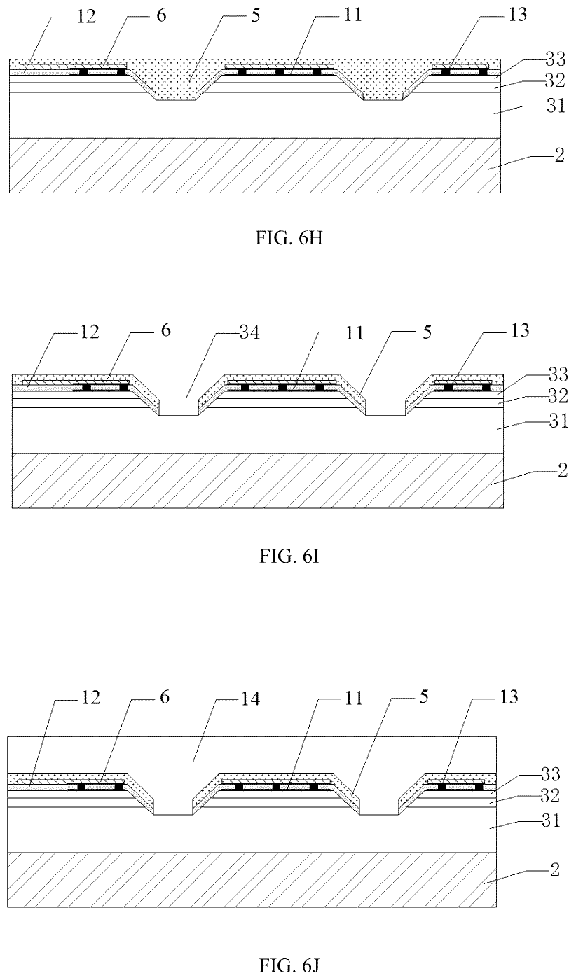

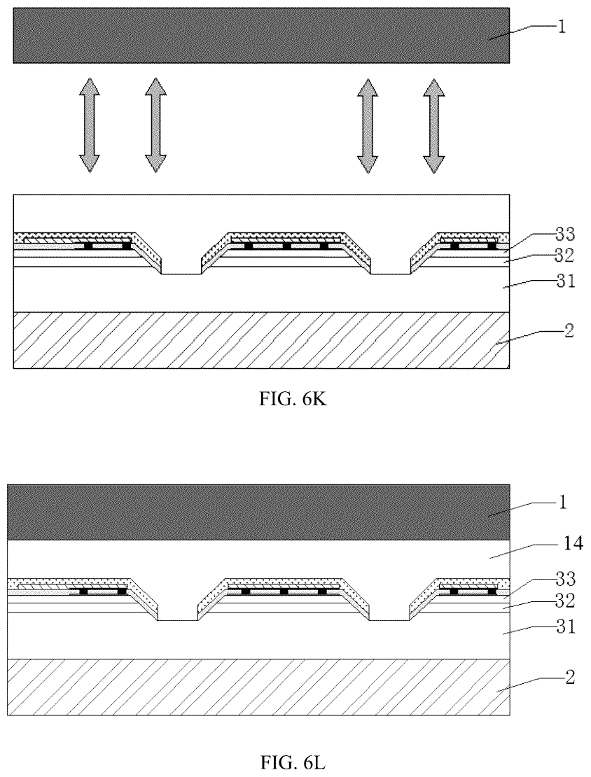

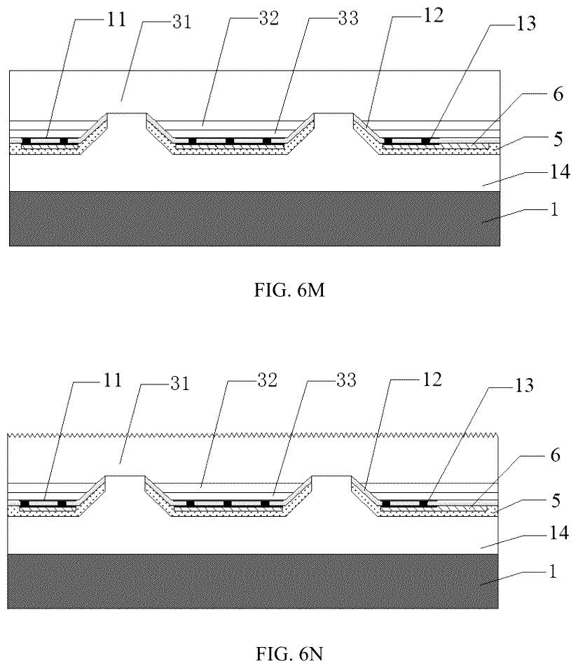

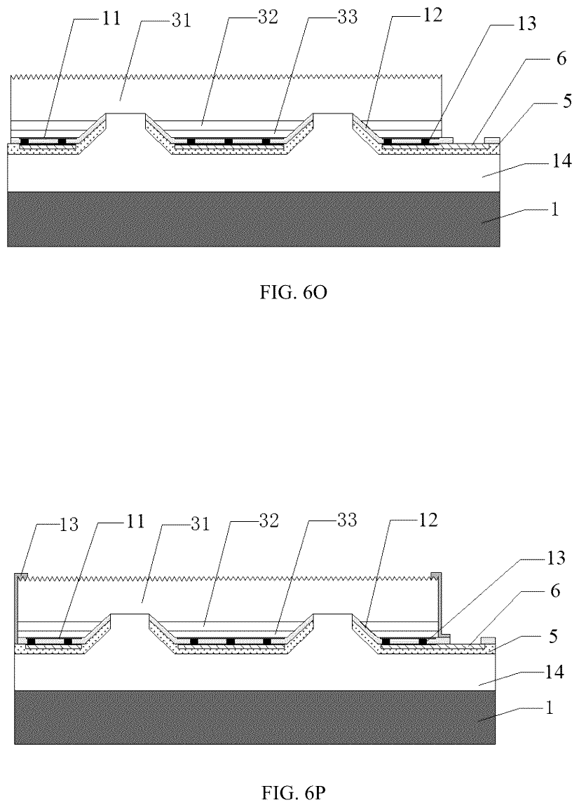

S601, as shown in FIG. 6A, provide a growth substrate 2.

In an embodiment of the present disclosure, the growth substrate 2 is made of any one or any combination of sapphire (Al₂O₃), SiC, GaAs, GaN, ZnO, Si, GaP, InP, Ge, and Ga₂O₃.

S602. As shown in FIG. 6B, prepare an epitaxial stack 3 on the surface of the growth substrate 2, the epitaxial stack 3 includes the first-type semiconductor layer 31, the active region 32, and the second-type semiconductor layer 33, stacked in sequence along a first direction. The first direction is perpendicular to the growth substrate 2 and is directed from the growth substrate 2 to the epitaxial stack 3.

The types of the first-type semiconductor layer 31, the active region 32, and the second-type semiconductor layer 33 of the epitaxial stack 3 are not limited in embodiments of the present disclosure. For example, the first-type semiconductor layer 31 may be but not limited to an N-type GaN layer, and correspondingly, the second-type semiconductor layer 33 may be but not limited to a P-type GaN layer.

S603, as shown in FIG. 6C, form a through hole 34 and a light-emitting mesa 35 in the epitaxial stack 3 through an etching process, and the through hole 34 exposes a part of the surface of the first-type semiconductor layer 31.

In an embodiment of the present disclosure, the vertical LED chip has n through holes 34, where n is a positive integer not less than 2. In order to highlight the technical solution points of the present disclosure, FIG. 6C only shows two through holes 34 in the vertical structure LED chip. In the actual use process, the vertical structure LED chip may contain a number of through holes, depending on the specific circumstances, which is not limited in this present disclosure.

S604. As shown in FIG. 6D, an ohmic contact layer 11 is formed on the light-emitting mesa 35, and the ohmic contact layer 11 is used to promote the ohmic contact between the metal and the semiconductor material.

In an embodiment of the present disclosure, the ohmic contact layer 11 includes a metal ohmic contact layer or a transparent conductive layer. In an embodiment of the present disclosure, in order to avoid the light being absorbed by metal, the ohmic contact layer 11 may be a transparent conductive layer.

S605. As shown in FIG. 6E, a dielectric layer 12 is formed on the surface of the ohmic contact layer 11, and the dielectric layer 12 has an opening 121 exposing the ohmic contact layer 11.

In an embodiment of the present disclosure, the dielectric layer 12 covers the ohmic contact layer 11 and extends to the sidewall of the through hole 34.

In an embodiment of the present disclosure, the dielectric layer 12 includes any one or any combination of a silicon oxide layer, a silicon nitride layer, a silicon oxynitride layer, a titanium oxide layer, an aluminum oxide layer, a magnesium fluoride layer, and a hafnium oxide layer.

In an embodiment of the present disclosure, the dielectric layer 12 has m openings 121, where m is a positive integer not less than 2. In order to highlight the technical solution points of the present disclosure, FIG. 6E only shows some openings of the dielectric layer. In actual use, the dielectric layer may contain several openings, depending on the situation. However, the present disclosure does not limit the number and the specific arrangement of the openings 121.

S606, as shown in FIG. 6F, prepared a metal reflective layer 13, the metal reflective layer 13 is embedded in the dielectric layer 12 through the opening 121 to form contact with the second-type semiconductor layer 33.

In an embodiment of the present disclosure, the metal reflective layer 13 includes any one or any combination of an aluminum metal layer, a silver metal layer, an Au metal layer, a platinum metal layer, a lead metal layer, a nickel metal layer, an indium metal layer, a zinc metal layer, a chromium metal layer, a niobium metal layer, a titanium metal layer, a tin metal layer, and a rhodium metal layer.

S607, as shown in FIG. 6G, prepared an integrated metal layer 6, the integrated metal layer 6 is stacked on the surface of the metal reflective layer 13.

In an embodiment of the present disclosure, the integrated metal layer 6 includes Au metal material.

S608, as shown in FIG. 6H, prepare an insulating layer 5, the insulating layer 5 covers the integrated metal layer 6, and makes the surface of the epitaxial stack 3 form a plane. In an embodiment of the invention, the insulating layer 5 includes but is not limited to a silicon dioxide layer

S609, as shown in FIG. 6I, through an etching process, form a through hole 34 with an insulating layer 5 on the side wall of the through hole 34;

S610. As shown in FIG. 6J, prepare a conductive bonding layer 14, the conductive bonding layer 14 is stacked on the surface of the insulating layer 5, and embedded in the through hole 34 to form contact with the first-type semiconductor layer 31;

In an embodiment of the present disclosure, the conductive bonding layer 14 includes but is not limited to any one or any combination of Au, In, Ni, Sn, Ag, and Cu.

S611, as shown in FIG. 6K, provide a substrate 1, and through a bonding process, bond the substrate 1 and the conductive bonding layer 14 to form an integral body, as shown in FIG. 6L;

In an embodiment of the present disclosure, the substrate 1 includes a conductive substrate 1.

S612, as shown in FIG. 6M, peel off the growth substrate 2;

In an embodiment of the present disclosure, after the growth substrate 2 is peeled off to expose the first-type semiconductor layer 31, through a photolithography process, a roughened surface is formed on a side of the first-type semiconductor layer 31 facing away from the active region 32.

S613, as shown in FIG. 60, etch a part of the epitaxial stack 3 to the insulating layer 5, so that the integrated metal layer 6 has an exposed surface for electrical connection with the external driving device.

In an embodiment of the present disclosure, as shown in FIG. 6P, a passivation protection layer 10 is provided on the sidewall of the epitaxial stack 3, and the passivation protection layer 10 is made of insulating material. In an embodiment, the passivation protection layer 10 includes an insulating material layer having a reflection effect. In an embodiment, the passivation protection layer 10 may include a DBR mirror.

It can be seen from the above-mentioned technical solutions that the vertical LED chip provided by the present disclosure is provided with a dielectric layer 12 on the surface of the second-type semiconductor layer 33 facing away from the active region 32, and the metal reflective layer 13 is embedded in the dielectric layer 12 through the opening 12 to form contact with the second-type semiconductor layer 33; the integrated metal layer 6 is stacked on the surface of the metal reflective layer 13 facing away from the epitaxial stack 3, and the side of the integrated metal layer 6 facing the second-type semiconductor layer 33 is provided with an exposed surface for electrical connection with the external driving device; the insulating layer 5 is provided on the side of the epitaxial stack 3 facing the substrate 1, and covers the integrated metal layer 6. Therefore, an ODR (omnidirectional reflector) is formed on the surface of the epitaxial stack 3 by the cooperation of the dielectric layer 12 and the metal reflective layer 13, so that the light is reflected and emitted out from the upper surface of the LED chip, effectively improving the overall reflectivity of the chip, and increasing the light extraction efficiency. Meanwhile, by embedding the integrated metal layer 6, and using a metal material containing Au in the process of preparing the integrated metal layer 6, exposing a part of the surface of the integrated metal layer 6 by etching, the exposed surface of the integrated layer 6 undertakes the function of the PAD metal layer 9, and can conduct electrical connection with the external driving device. The contact electrode does not need to be prepared separately, and the conductive wire can be directly bonded to the integrated metal layer 6 during packaging, which saves costs. At the same time, Au has lower resistivity and higher thermal conductivity, so that the integrated metal layer 6 has good performances of excellent current spreading capability and low thermal resistance. In addition, different from the prior PAD metal layer, the side wall of the integrated metal layer 6 is covered in the insulating layer 5, which can better withstand the erosion of external water vapor, acid, and alkali, salt spray, etc., and improve the reliability of the chip.

Further, the epitaxial stack 3 has n through holes 34 exposing part of the surface of the first-type semiconductor layer 31, and the conductivity-type bonding layer 14 is stacked on the surface of the insulating layer 5 facing away from the integrated metal layer 6, embedded in the through hole 34 to form contact with the first-type semiconductor layer 31, thereby forming a first carrier injection lattice. Based on this structure, when the backside electrons are injected through the entire surface of the conductive substrate 1, each through hole 34 in the first carrier injection lattice has the same potential, so that the electrons can be injected uniformly.

Further, by preparing the dielectric layer 12 having m openings 121, wherein m is a positive integer not less than 2, the metal reflective layer 13 is embedded through the openings 121, thereby forming a second carrier point array injection point. Therefore, excessively concentrated recombination of electrons and holes can be avoided in the periphery of the first carrier injection lattice. Through the second carrier lattice injection point, the distribution of the current in the epitaxial stack 3 can be uniform, thereby effectively alleviating current congestion, reducing Auger recombination, and increasing internal quantum efficiency.

The manufacturing method of the vertical structure LED chip provided by the present disclosure realizes the beneficial effects of the above-mentioned vertical structure LED chip, and at the same time, the manufacturing process is simple and convenient, which saves cost, and is convenient for production.

The implementation principles and technical benefits of the device provided by the embodiments of the present disclosure are the same as those of the aforementioned method embodiment. For brief description, for the parts not mentioned in the device embodiment, reference may be made to the corresponding content in the aforementioned method embodiments. Those skilled in the art can clearly understand that, for the convenience and brevity of description, the specific working processes of the above-described systems, devices, and units can refer to the corresponding processes in the above-mentioned method embodiments, and will not be repeated here.

Each embodiment in this specification is described in a progressive manner, each embodiment focuses on the difference from other embodiments, and the same and similar parts of each embodiment can be referred to each other.

It should also be noted that in the present disclosure, relational terms such as first and second, etc. are only used to distinguish one entity or operation from another entity or operation, and do not necessarily require or imply that these entities or operations have any such actual relationship or order exists between. Moreover, the term “comprises”, “includes” or any other variation thereof is intended to cover a non-exclusive inclusion such that an article or device comprising a set of elements includes not only those elements but also other elements not expressly listed, or also include elements inherent in the article or device. Without further limitations, an element defined by the phrase “comprising a . . . ” does not exclude the presence of additional identical elements in an article or device comprising the aforementioned element.

The above description of the disclosed embodiments is provided to enable any skilled in the art to make or use the present disclosure. Various modifications to these embodiments will be readily apparent to those skilled in the art, and the general principles defined herein may be implemented in other embodiments without departing from the spirit or scope of the present disclosure. Therefore, the present disclosure will not be limited to the embodiments recited herein, but is to be accorded the widest scope consistent with the principles and novel features disclosed herein.

1. A light-emitting structure, comprising:
a substrate, and
a first metal layer, an insulating layer, an integrated metal layer, and an epitaxial stack, disposed above the substrate;
wherein the epitaxial stack comprises a first-type semiconductor layer, an active region, and a second-type semiconductor layer, stacked in sequence along a direction, the direction being perpendicular to the substrate and being directed from the epitaxial stack to the substrate,
wherein the epitaxial stack has a through hole exposing a part of a surface of the first-type semiconductor layer,
wherein the integrated metal layer is disposed on a surface of the second-type semiconductor layer facing away from the active region, and the integrated metal layer comprises an exposed surface on a side of the integrated metal layer facing the second-type semiconductor layer, the exposed surface being configured to electrically connect with an external driving device;
wherein the insulating layer is disposed on a side of the epitaxial stack facing the substrate, covers the integrated metal layer and an exposed surface of the epitaxial stack;
wherein the first metal layer is stacked on a surface of the insulation layer facing away from the integrated metal layer, embedded in the through hole to form contact with the first-type semiconductor layer, and insulated from a sidewall of the through hole; and
wherein the substrate is stacked on a surface of the first metal layer facing away from the epitaxial stack.

2. The light-emitting structure according to claim 1, wherein the integrated metal layer is made of any one or any combination of Au, copper, palladium, or aluminum.

3. The light-emitting structure according to claim 1, wherein a sidewall of the integrated metal layer is covered by the insulating layer.

4. The light-emitting structure according to claim 1, further comprising:
an ohmic reflective layer, disposed on a surface of the integrated metal layer facing the second-type semiconductor layer, the ohmic reflective layer is configured to perform ohmic contact and realize light reflection.

5. The light-emitting structure according to claim 4, wherein the ohmic reflective layer is made of any one or any combination of indium tin oxide, zinc tin oxide, indium zinc tin oxide, indium aluminum tin oxide, indium gallium tin oxide, aluminum zinc oxide, antimony tin oxide, gallium zinc oxide, IrOx, RuOx, indium, tin, aluminum, Au, platinum, zinc, silver, titanium, lead, nickel, rhodium, or molybdenum.

6. The light-emitting structure according to claim 1, wherein the substrate comprises a conductive substrate.

7. The light-emitting structure according to claim 1, further comprising:
a passivation layer, disposed on a sidewall of the epitaxial stack.

8. The light-emitting structure according to claim 1, wherein the insulating layer extends to the sidewall of the through hole, so that the first metal layer is insulated from the sidewall of the through hole.

9. The light-emitting structure according to claim 1, further comprising:
a dielectric layer, stacked on a surface of the second-type semiconductor layer facing away from the active region, and
a metal reflective layer, in contact with the second-type semiconductor layer through an opening embedded in the dielectric layer;
wherein the integrated metal layer is stacked on a surface of the metal reflective layer facing away from the epitaxial stack.

10. The light-emitting structure according to claim 9, wherein the dielectric layer has m openings, wherein m is a positive integer not less than 2.

11. The light-emitting structure according to claim 9, comprising n through holes, wherein n is a positive integer not less than 2.

12. The light-emitting structure according to claim 9, further comprising:
a filling structure, disposed in the through hole,
wherein the filling structure comprises independent epitaxial pillars formed by etching in the epitaxial stack, or the filling structure comprises any one or any combination of insulating materials and metals.

13. The light-emitting structure according to claim 8, wherein the dielectric layer comprises any one or any combination of a silicon oxide layer, a silicon nitride layer, a silicon oxynitride layer, a titanium oxide layer, an aluminum oxide layer, a magnesium fluoride layer, or a hafnium oxide layer.

14. The light-emitting structure according to claim 9, wherein the metal reflective layer comprises any one or any combination of an aluminum metal layer, a silver metal layer, an Au metal layer, a platinum metal layer, a lead metal layer, a nickel metal layer, an indium metal layer, a zinc metal layer, a chromium metal layer, a niobium metal layer, a titanium metal layer, a tin metal layer, or a rhodium metal layer.

15. The light-emitting structure according to claim 9, wherein the first-type semiconductor layer has a roughened surface on a side facing away from the active region.

16. The light-emitting structure according to claim 9, wherein further comprising:
an ohmic contact layer, disposed on a surface of the second-type semiconductor layer facing away from the active region,
wherein the dielectric layer is stacked on a surface of the ohmic contact layer, and the ohmic contact layer forms ohmic contact with the metal reflective layer.

17. The light-emitting structure according to claim 9, further comprising:
a passivation layer, disposed on a sidewall of the epitaxial stack.

18. The light-emitting structure according to claim 9, wherein the metal reflective layer extends to the sidewall of the through hole by being attached to the dielectric layer, and the insulating layer covers a surface of the metal reflective layer.

19. A method for manufacturing a light-emitting structure, comprising:
providing a growth substrate;
preparing an epitaxial stack on a surface of the growth substrate, the epitaxial stack comprising a first-type semiconductor layer, an active region, and a second-type semiconductor layer, stacked in sequence along a direction, and the direction being perpendicular to the growth substrate and directed from the growth substrate to the epitaxial stack;
forming a first through hole and a light-emitting mesa in the epitaxial stack by an etching process, the first through hole exposing a part of a surface of the first-type semiconductor layer;
forming an ohmic reflective layer on the light-emitting mesa, the ohmic reflective layer being configured to perform ohmic contact and realize light reflection;
depositing a first insulating layer, the first insulating layer filling the first through hole and extending to a sidewall of the ohmic reflective layer;
preparing an integrated metal layer stacked on a surface of the ohmic reflective layer and the insulating layer;
depositing a second insulating layer, the second insulating layer covering the integrated metal layer;
forming a second through hole with the first insulating layer left on a side wall of the second through hole through an etching process;
preparing a first metal layer to obtain an intermediate structure, the first metal layer being stacked on a surface of the insulating layer and embedded in the second through hole to form contact with the first-type semiconductor layer;
fixing the intermediate structure on a substrate through a bonding process, the substrate being conductive and formed on a surface of the first metal layer;
peeling off the growth substrate; and
etching a part of the epitaxial stack so that the integrated metal layer has an exposed surface configured to electrically connect with an external driving device.

20. A light-emitting device, comprising:
a driving device, configured to transmit a driving signal to a light-emitting structure; and
the light-emitting structure, comprising:
a substrate, and
a first metal layer, an insulating layer, an integrated metal layer, and an epitaxial stack, disposed above the substrate;
wherein the epitaxial stack comprises a first-type semiconductor layer, an active region, and a second-type semiconductor layer, stacked in sequence along a direction, the direction being perpendicular to the substrate and being directed from the epitaxial stack to the substrate,
wherein the epitaxial stack has a through hole exposing a part of a surface of the first-type semiconductor layer,
wherein the integrated metal layer is disposed on a surface of the second-type semiconductor layer facing away from the active region, and the integrated metal layer comprises an exposed surface on a side of the integrated metal layer facing the second-type semiconductor layer, the exposed surface being configured to electrically connect with an external driving device;
wherein the insulating layer is disposed on a side of the epitaxial stack facing the substrate, covers the integrated metal layer and an exposed surface of the epitaxial stack;
wherein the first metal layer is stacked on a surface of the insulation layer facing away from the integrated metal layer, embedded in the through hole to form contact with the first-type semiconductor layer, and insulated from a sidewall of the through hole; and
wherein the substrate is stacked on a surface of the first metal layer facing away from the epitaxial stack.
